(19) United States
(12) Patent Application Publication
(10) Pub. No.: US 2012/0050992 A1
(43) Pub. Date: Mar. 1, 2012

(54) SUPERCAPACITOR MODULE

(75) Inventors: Senug Hyun Ra, Gyeonggi-do (KR); Bae Kyun Kim, Gyeonggi-do (KR); Yong Wook Kim, Gyeonggi-do (KR)

(73) Assignee: SUMSUNG Electro-Mechanics Co., Ltd.

(21) Appl. No.: 13/219,135

(22) Filed: Aug. 26, 2011

(30) Foreign Application Priority Data
Aug. 27, 2010 (KR) 10-2010-0083374

(51) Int. Cl. H05K 7/20

(52) U.S. Cl. 361/699

(57) ABSTRACT

Provided is a supercapacitor module including a plurality of supercapacitors, a water cooling jacket including containing parts for containing the supercapacitors, respectively, and radiating heat emitted from side surfaces of the supercapacitors, an inlet port for introducing cooling water supplied into the water cooling jacket from the exterior, and an outlet port for releasing the cooling water discharged from the water cooling jacket to the exterior. Therefore, it is possible to provide the supercapacitor module capable of increasing a radiation effect.

### CROSS-REFERENCE TO RELATED APPLICATIONS

This application claims the benefit of Korean Patent Application No. 10-2010-0083374 filed with the Korea Intellectual Property Office on Aug. 27, 2010, the disclosure of which is incorporated herein by reference.

### BACKGROUND OF THE INVENTION

1. Field of the Invention

The present invention relates to a supercapacitor module, and more particularly, to a supercapacitor module including a water cooling jacket.

2. Description of the Related Art

Supercapacitors have been attracting attention as high quality energy sources in a renewable energy system that can be applied to electric vehicles, hybrid vehicles, fuel cell vehicles, heavy equipment, mobile electronic terminals, and so on.

Such supercapacitors may be classified into electrical double layer capacitors using an electrical double layer theory, and hybrid supercapacitors using electrochemical oxidation-reduction reaction. Here, while the supercapacitors are widely used in fields that require high-output energy characteristics, they have a smaller capacity than in secondary batteries. The hybrid supercapacitors have been widely researched as new alternatives to improve capacitive characteristics of the electrical double layer capacitors. In particular, a lithium ion capacitor (LIC) among the hybrid supercapacitors may have a storage capacity three to four times larger than that of the electrical double layer capacitors.

Such supercapacitors may include cathodes and anodes, which are alternately laminated, and separators disposed between the laminated cathodes and anodes to electrically separate the cathodes and anodes from each other.

Meanwhile, since the supercapacitors have high output characteristics and low energy storage characteristics, a supercapacitor module in which a plurality of supercapacitors are connected in series or parallel is used in a vehicle or heavy equipment.

At this time, while the supercapacitor module can improve energy storage characteristics by driving the plurality of supercapacitors, since heat generated during driving of the supercapacitor module is also abruptly increased, reliability or stability of the supercapacitor module may be decreased. Therefore, the number of the supercapacitors provided in the supercapacitor module and use environments of the supercapacitor module must be restricted.

For this reason, the supercapacitor module still needs a technique of effectively radiating heat generated during driving of the plurality of supercapacitors.

### SUMMARY OF THE INVENTION

The present invention has been invented in order to overcome the above-described problems and it is, therefore, an object of the present invention to provide a supercapacitor module includes a water cooling jacket and capable of radiating heat generated from each supercapacitor.

In accordance with one aspect of the present invention to achieve the object, there is provided a supercapacitor module including: a plurality of supercapacitors; a water cooling jacket including containing parts for containing the supercapacitors, respectively, and radiating heat emitted from side surfaces of the supercapacitors; an inlet port for introducing cooling water supplied into the water cooling jacket from the exterior; and an outlet port for releasing the cooling water discharged from the water cooling jacket to the exterior.

Here, the containing parts may be formed to have a groove or hole shape corresponding to the supercapacitors.

In addition, the water cooling jacket may include water cooling blocks having water channels through which cooling water flows and disposed around the supercapacitors to support the supercapacitors.

Further, the containing parts may be formed by coupling the water cooling blocks.

Furthermore, the water cooling jacket may further include a water cooling connection part disposed under the water cooling blocks to connect the water cooling blocks to each other, and supplying the cooling water to the water cooling blocks.

In addition, the water cooling connection part may have a substrate shape disposed under the plurality of supercapacitors and the water cooling blocks.

Further, the water cooling connection part may include a connection water channel for connecting the inlet port, the water channel of the water cooling block and the outlet port to each other.

Furthermore, the water cooling block may include a first water cooling block for containing portions of the supercapacitors disposed in one row among the plurality of supercapacitors; and a second water cooling block connected to the first water cooling block and containing the other portions of the supercapacitors disposed in one row.

In addition, the supercapacitor module may further include a radiation plate disposed on at least one surface of upper and lower surfaces of the plurality of supercapacitors, and having a cooling flow path through which a cooling media flows.

In accordance with another aspect of the present invention to achieve the object, there is provided a supercapacitor module including: a plurality of supercapacitors; a water cooling jacket including containing parts for containing the supercapacitors, respectively; an inlet port for introducing cooling water supplied into the water cooling jacket from the exterior; and an outlet port for releasing the cooling water discharged from the water cooling jacket to the exterior, wherein the water cooling jacket comprises a plurality of water cooling blocks for moving the cooling water in a vertical direction to radiate heat emitted from side surfaces of the supercapacitors.

Here, the containing parts may be formed by coupling the water cooling blocks disposed around the supercapacitors.

In addition, the water cooling jacket may further include a water cooling connection part disposed under the water cooling blocks to connect the water cooling blocks to each other, and supplying the cooling water to the water cooling blocks.

Further, the water cooling connection part may have a substrate shape to support the supercapacitors, and the water cooling connection part may be connected to lower parts of the supercapacitors to radiate heat emitted from the lower parts of the supercapacitors.

In accordance with still another aspect of the present invention to achieve the object, there is provided a supercapacitor module including: a plurality of supercapacitors; a water cooling jacket including containing parts for containing the supercapacitors, respectively; an inlet port for introducing cooling water supplied into the water cooling jacket; and an outlet port for releasing the cooling water discharged from the water cooling jacket to the exterior, wherein the water cooling jacket comprises a water cooling block for moving the cooling water in vertical and horizontal directions to radiate heat emitted from side surfaces of the supercapacitors.

Here, the water cooling block may include a first water cooling block for containing portions of the supercapacitors disposed in one row among the plurality of supercapacitors; and a second water cooling block connected to the first water cooling block and containing the other portions of the supercapacitors disposed in one row.

In addition, the supercapacitor module may further include a water cooling connection part for connecting the first and second water cooling blocks to each other, and supplying cooling water to the first and second water cooling blocks.

Further, the containing parts may have a groove or hole shape formed in a body of the water cooling block, and the body of the water cooling block may include a water channel through which cooling water flows.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a schematic perspective view of a supercapacitor module in accordance with an exemplary embodiment of the present invention;

FIG. 2 is a perspective view of a first type of water cooling jacket installed at the supercapacitor in accordance with an exemplary embodiment of the present invention;

FIG. 3 is a cross-sectional view taken along line I-I′ shown in FIG. 2;

FIG. 4 is a perspective view of a second type of water cooling jacket installed at the supercapacitor in accordance with an exemplary embodiment of the present invention; and

FIG. 5 is a perspective view of a third type of water cooling jacket installed at the supercapacitor in accordance with an exemplary embodiment of the present invention.

### DETAILED DESCRIPTION OF THE PREFERABLE EMBODIMENTS

Hereinafter, embodiments of the present invention for a supercapacitor module will be described in detail with reference to the accompanying drawings. The following embodiments are provided as examples to fully convey the spirit of the invention to those skilled in the art.

Therefore, the present invention should not be construed as limited to the embodiments set forth herein and may be embodied in different forms. And, the size and the thickness of an apparatus may be overdrawn in the drawings for the convenience of explanation. The same components are represented by the same reference numerals hereinafter.

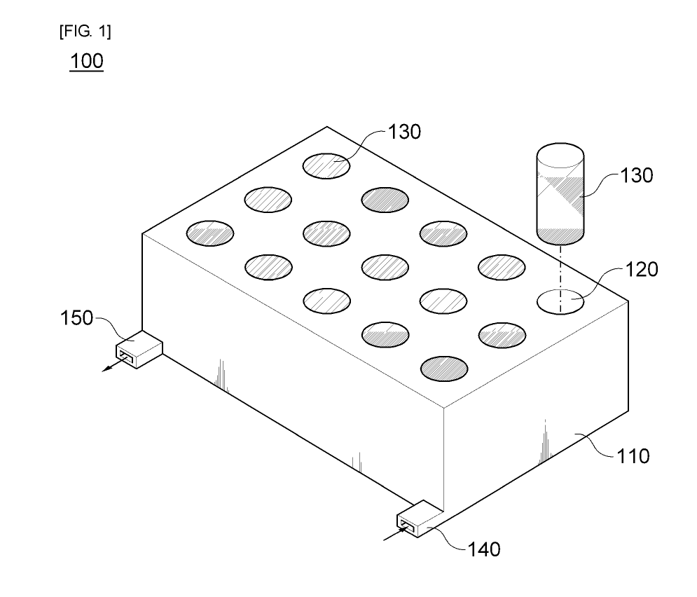

FIG. 1 is a schematic perspective view of a supercapacitor module in accordance with an exemplary embodiment of the present invention.

Referring to FIG. 1, a supercapacitor module 100 in accordance with the embodiment of the present invention may include a water cooling jacket 110 including a plurality of containing parts 120, and supercapacitors 130 contained in the containing parts 120, respectively.

The water cooling jacket 110 may include a water channel formed in a body and through which cooling water flows, cooing heat through the flow of the cooling water. Here, the water cooling jacket 110 may be formed of a material having good heat conductivity, for example, a metal material such as aluminum, copper, and so on. However, the material of the water cooling jacket according to the embodiment of the present invention is not limited thereto.

The supercapacitors 130 are inserted into the containing parts 120 formed in the water cooling jacket 110, and thus, both bottom surfaces and side surfaces of the supercapacitors 130 can be in contact with the water cooling jacket 110. Therefore, heat generated from the bottom surfaces and side surfaces of the supercapacitors 130 can be effectively radiated. In addition, since the supercapacitors 130 are inserted into the containing parts 120 of the water cooling jacket 110 to complete assembly thereof, assemblability of the supercapacitor module 100 can be improved.

Further, the containing parts 120 may have a shape corresponding to that of the supercapacitors 130. For example, when the supercapacitor 130 has a cylindrical shape, the containing part 120 may be a cylindrical groove or a cylindrical hole. Here, the groove means a shape received into a body of the water cooling jacket 110, and the hole means an opening passing through the body of the water cooling jacket 110. Therefore, since the supercapacitors 130 can be closely inserted into the interior of the containing parts 120 to obtain adhesion between the supercapacitors 130 and the water cooling jacket 110, a radiation effect of the supercapacitors 130 can be increased.

The water cooling jacket 110 is configured to pass between the plurality of supercapacitors 130 to effectively radiate heat generated from side surfaces of the supercapacitors 130, so that reliability and stability of the supercapacitor module 100 with respect to the heat generation can be accomplished, and restriction to the number of the supercapacitors 130 included in the supercapacitor module 100 or a work environment of the supercapacitor module 100 can be removed.

The supercapacitor module 100 may further include an inlet port 140 for receiving cooling water from the exterior and supplying it into the water cooling jacket 110, and an outlet port 150 for releasing the cooling water discharged from the water cooling jacket 110 to the exterior.

Here, the inlet port 140 may be connected to a water channel installed inside the water cooling jacket 110. In addition, while not shown, the inlet port 140 is connected to a pump for supplying cooling water into the inlet port 140 to effectively control a speed and an amount of the cooling water inserted into the water cooling jacket 110.

Here, while the inlet port 140 and the outlet port 150 may be disposed at a lower part of the supercapacitor module 100, it is not limited thereto. For example, the inlet port 140 may be disposed at an upper part of the supercapacitor module 100 to easily introduce the cooling water into the water cooling jacket 110, and the outlet port 150 may be disposed at the lower part of the supercapacitor module 100 to easily discharge the cooling water from the water cooling jacket 110.

In addition, while not shown, the supercapacitor module 100 may further include a radiation plate installed on at least one surface of upper and lower surfaces of the plurality of supercapacitors 130. Here, the radiation plate may include a cooling flow path through which a cooling media flows. Therefore, since heat generated from at least one surface of the upper and lower surfaces of the supercapacitor module 100, a radiation effect of the supercapacitor module 100 can be further increased.

Hereinafter, the water cooling jacket installed at the supercapacitor of the present invention will be described in detail.

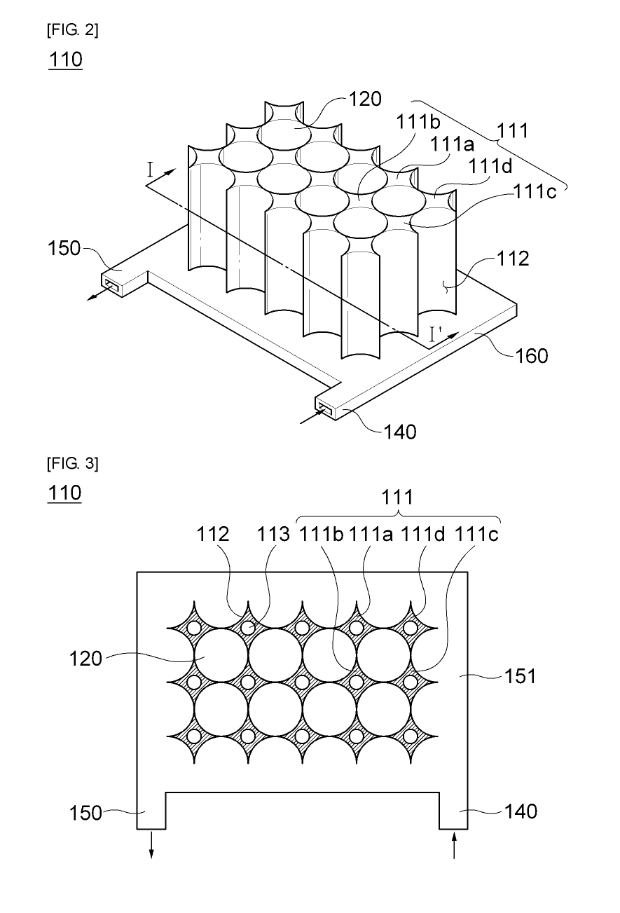

FIG. 2 is a perspective view of a first type of water cooling jacket installed at the supercapacitor in accordance with an exemplary embodiment of the present invention.

FIG. 3 is a cross-sectional view taken along line I-I′ shown in FIG. 2.

Referring to FIGS. 2 and 3, a first type of water cooling jacket 110 installed at the supercapacitor 130 in accordance with an exemplary embodiment of the present invention may include a water cooling connection part 160, and a plurality of water cooling blocks 111 projecting upward from the water cooling connection part 160.

The water cooling jacket 110 may include containing parts 120 for containing supercapacitors 130. Here, the containing parts 120 may be formed by coupling the water cooling blocks 111 disposed around the supercapacitors 130. For example, each of the water cooling blocks 111 may include first, second, third and fourth water cooling blocks 111a, 111b, 111c and 111d disposed around the supercapacitor 130. Here, when the supercapacitor 130 has a cylindrical shape, each sidewall 112 of the first, second, third and fourth water cooling blocks 111a, 111b, 111c and 111d may be recessed in a fan shape. Here, the respective sidewalls 112 of the first, second, third and fourth water cooling blocks 111a, 111b, 111c and 111d are coupled to each other to form a cylindrical containing part 120. Here, each water cooling block 111 may include a water channel 113 through which cooling water flows. Therefore, the cooling water can vertically circulate through the water channel 113 of the water cooling block 111. That is, as the cooling water vertically and repeatedly flows in the water cooling block 111 disposed between the supercapacitors 130, heat generated from side surfaces of the supercapacitors 130 can be effectively radiated.

Here, the water cooling connection part 160 may have a substrate shape. The water cooling connection part 160 may be disposed under the plurality of water cooling blocks 111 to support the plurality of water cooling blocks 111. In addition, the water cooling connection part 160 may be collected to lower parts of the supercapacitors 130 contained in the water cooling jacket 110 as well as the water cooling blocks 111 to support the plurality of supercapacitors 130 and radiate heat generated from the lower parts of the supercapacitors 130.

Further, the water cooling connection part 160 may include a connection water channel through which cooling water flows. Here, the connection water channel may be connected to the inlet port 140 for introducing cooling water, and the outlet port 150 for discharging the cooling water. Therefore, the cooling water introduced from the inlet port 140 can be supplied to the water cooling blocks 111 through the connection water channel of the water cooling connection part 160. Furthermore, the cooling water discharged from the water cooling blocks 111 can be discharged to the exterior through the outlet port 150 via the connection water channel of the water cooling connection part 160.

In addition, while not shown, a radiation plate for covering upper surfaces of the plurality of supercapacitors 130 may be further provided. Here, the radiation plate may include a cooling flow path for circulating a cooling media formed therein. Here, the cooling media may be a liquid such as cooling water, high-volatile solvent, for example, acetone, alcohol, and so on, or a gas such as Freon. Therefore, the supercapacitor module 100 can radiate heat generated from the upper surfaces of the supercapacitors 130 as well as the side and lower surfaces of the supercapacitors 130, further improving a radiation effect of the supercapacitor module 100.

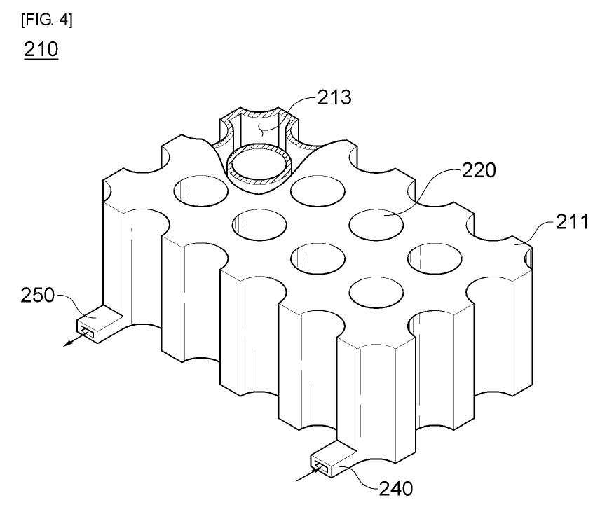

FIG. 4 is a perspective view of a second type of water cooling jacket installed at the supercapacitor in accordance with an exemplary embodiment of the present invention.

Referring to FIG. 4, a second type of water cooling jacket 210 installed at the supercapacitor in accordance with an exemplary embodiment of the present invention may include a water cooling block 211 projecting upward therefrom, an inlet port 240 for supplying cooling water into the water cooling block 211, and an outlet port 250 for discharging the cooling water from the water cooling block 211. Here, while the inlet port 240 and the outlet port 250 may be disposed at a lower part of the water cooling block 211, it is not limited thereto. For example, the inlet port 240 may be disposed at an upper part of the water cooling block 211 to easily introduce the cooling water into the water cooling block 211. In addition, the outlet port 250 may be disposed at the lower part of the water cooling block 211 to easily discharge the cooling water.

The water cooling block 211 may include containing parts 220 for containing supercapacitors 130 (see FIG. 1). Here, the containing parts 220 may include grooves or holes through which the supercapacitors 130 can be inserted. Here, the containing parts may have a shape corresponding to the supercapacitors 130. Thus, the supercapacitors 130 can be in close contact with the water cooling block 211 to further improve a radiation effect of the supercapacitors 130.

Here, when the containing parts 220 have a groove shape, the lower parts of the supercapacitors 130 can be in contact with the lower part of the water cooling block 211 so that heat generated from the lower parts of the supercapacitors 130 can be easily discharged. Here, a radiation plate for covering upper surfaces of the plurality of supercapacitors 130 may be further provided to radiate heat generated from upper parts of the supercapacitors.

In addition, when the containing parts 220 has a hole shape, radiation plates may be further installed at upper and lower parts of the supercapacitors 130 to effectively radiate heat generated from all surfaces of the supercapacitors 130.

The water cooling block 211 may include a water channel 213 through which cooling water flows. Here, the water channel 213 may be defined by outer and inner plates of the water cooling block 211. Thus, the water channel 213 of the water cooling block 211 may be integrally formed such that the cooling water can flow through the water channel 213 of the water cooling block 211 in vertical and horizontal directions. Therefore, the cooling water moves in vertical and horizontal directions of the supercapacitors 130 to radiate heat formed in the supercapacitors, further increasing a radiation effect of the supercapacitor module 100 (see FIG. 1).

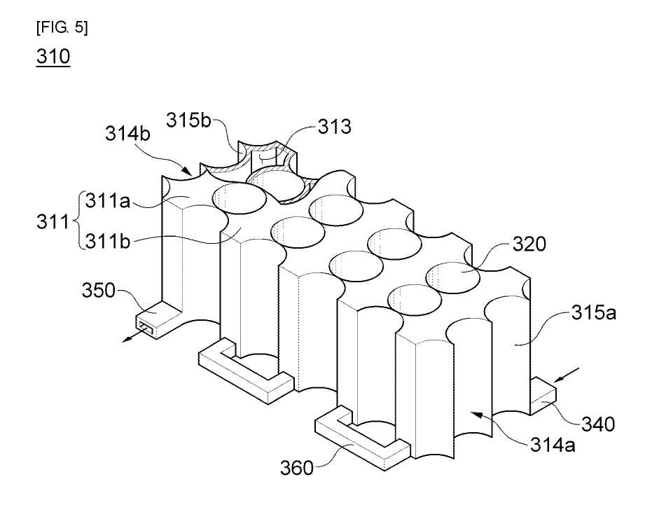

FIG. 5 is a perspective view of a third type of water cooling jacket installed at the supercapacitor in accordance with an exemplary embodiment of the present invention.

Referring to FIG. 5, a third type of water cooling jacket 310 installed at the supercapacitor in accordance with an exemplary embodiment of the present invention may include a plurality of water cooling blocks 311 projecting upward therefrom, an inlet port 340 for supplying cooling water into the water cooling blocks 311, and an outlet port 350 for discharging the cooling water from the water cooling blocks 311.

Here, each of the water cooling blocks 311 may include first and second water cooling blocks 311a and 311b coupled to each other to form a plurality of containing parts 320 disposed in one row. Here, when the supercapacitors has a cylindrical shape, the first water cooling block 311a may be provided with a first sidewall 314a including a first groove 315a having a hemispherical shape, and the second water cooling block 311b may be provided with a second sidewall 314b including a second groove 315b having a hemispherical shape symmetrical to the first sidewall 314a. Here, the first and second water cooling blocks 311a and 311b may be coupled to oppose the first and second sidewalls 314a and 314b each other to form containing parts 320 for containing the supercapacitors 130.

Here, the first and second sidewalls 314a and 314b may include pluralities of first and second grooves 315a and 315b, respectively, to form a plurality of containing parts 320 when the first and second water cooling blocks 311a and 311b are coupled to each other. That is, the first water cooling block 311a may contain portions of the supercapacitors disposed in one row among the plurality of supercapacitors 130. In addition, the second water cooling block 311b may be coupled to the first water cooling block 311a and contain the other portions of the supercapacitors 130 disposed in one row.

The first and second water cooling blocks 311a and 311b may include water channels 313 through which cooling water flows, respectively.

The first and second water cooling blocks 311a and 311b may be connected by a water cooling connection part 360. Here, the water channels 313 installed at the first and second water cooling blocks 311a and 311b may be connected by the water cooling connection part 360. In addition, the water cooling connection part 360 may be connected to the inlet port 340 for introducing cooling water, and the outlet port 350 for discharging the cooling water discharged from the first and second water cooling blocks 311a and 311b.

The first and second water cooling blocks 311a and 311b are connected by the water cooling connection part 360 so that the cooling water can flow in vertical and horizontal directions. Therefore, the cooling water can move in vertical and horizontal directions of the supercapacitors 130 to effectively radiate heat generated in the supercapacitors.

Therefore, as described in the embodiment of the present invention, the supercapacitor module of the present invention contains the plurality of supercapacitors in the water cooling jacket so that heat generated from the side surfaces of the supercapacitors can be effectively radiated.

In addition, the water cooling jacket installed at the supercapacitor module of the present invention includes the containing parts for containing the plurality of supercapacitors, and thus, assemblability of the supercapacitor module can be improved.

Further, since the supercapacitor module of the present invention may further include a radiation plate installed at the upper or lower parts of the supercapacitors, it is possible to effectively remove the heat from the upper or lower part of the supercapacitor module.

Furthermore, the water cooling jacket installed at the supercapacitor module of the present invention can have a cooling water flow in vertical and horizontal directions of the supercapacitors, more effectively removing heat from the supercapacitors.

As can be seen from the foregoing, the supercapacitor module of the present invention includes the water cooling jacket between the supercapacitors, effectively removing heat generated from the side surfaces of the supercapacitors.

In addition, since the water cooling jacket installed at the supercapacitor module of the present invention can a cooling water flow in vertical and horizontal direction of the supercapacitors, it is possible to more effectively remove the heat from the supercapacitors.

Further, since the water cooling jacket installed at the supercapacitor module of the present invention includes the containing parts for containing the plurality of supercapacitors, assemblability of the supercapacitor module can be improved.

Furthermore, the supercapacitor module of the present invention may further include the radiation plate installed at the upper or lower part of the supercapacitor to effectively remove heat generated from the upper or lower part of the supercapacitor module.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

What is claimed is:

1. A supercapacitor module comprising:
a plurality of supercapacitors;
a water cooling jacket including containing parts for containing the supercapacitors, respectively, and radiating heat emitted from side surfaces of the supercapacitors;
an inlet port for introducing cooling water supplied into the water cooling jacket from the exterior; and
an outlet port for releasing the cooling water discharged from the water cooling jacket to the exterior.

2. The supercapacitor module according to claim 1, wherein the containing parts are formed to have a groove or hole shape corresponding to the supercapacitors.

3. The supercapacitor module according to claim 1, wherein the water cooling jacket includes water cooling blocks having water channels through which cooling water flows and disposed around the supercapacitors to support the supercapacitors.

4. The supercapacitor module according to claim 3, wherein the containing parts are formed by coupling the water cooling blocks.

5. The supercapacitor module according to claim 3, wherein the water cooling jacket further comprises a water cooling connection part disposed under the water cooling blocks to connect the water cooling blocks to each other, and supplying the cooling water to the water cooling blocks.

6. The supercapacitor module according to claim 5, wherein the water cooling connection part has a substrate shape disposed under the plurality of supercapacitors and the water cooling blocks.

7. The supercapacitor module according to claim 6, wherein the water cooling connection part includes a connection water channel for connecting the inlet port, the water channel of the water cooling block and the outlet port to each other.

8. The supercapacitor module according to claim 3, wherein the water cooling block comprises:
a first water cooling block for containing portions of the supercapacitors disposed in one row among the plurality of supercapacitors; and
a second water cooling block connected to the first water cooling block and containing the other portions of the supercapacitors disposed in one row.

9. The supercapacitor module according to claim 1, further comprising a radiation plate disposed on at least one surface of upper and lower surfaces of the plurality of supercapacitors, and having a cooling flow path through which a cooling media flows.

10. A supercapacitor module comprising:
a plurality of supercapacitors;
a water cooling jacket including containing parts for containing the supercapacitors, respectively;
an inlet port for introducing cooling water supplied into the water cooling jacket from the exterior; and
an outlet port for releasing the cooling water discharged from the water cooling jacket to the exterior,
wherein the water cooling jacket comprises a plurality of water cooling blocks for moving the cooling water in a vertical direction to radiate heat emitted from side surfaces of the supercapacitors.

11. The supercapacitor module according to claim 10, wherein the containing parts are formed by coupling the water cooling blocks disposed around the supercapacitors.

12. The supercapacitor module according to claim 11, wherein the water cooling jacket further comprises a water cooling connection part disposed under the water cooling blocks to connect the water cooling blocks to each other, and supplying the cooling water to the water cooling blocks.

13. The supercapacitor module according to claim 12, wherein the water cooling connection part has a substrate shape to support the supercapacitors, and the water cooling connection part is connected to lower parts of the supercapacitors to radiate heat emitted from the lower parts of the supercapacitors.

14. A supercapacitor module comprising:
a plurality of supercapacitors;
a water cooling jacket including containing parts for containing the supercapacitors, respectively;
an inlet port for introducing cooling water supplied into the water cooling jacket; and
an outlet port for releasing the cooling water discharged from the water cooling jacket to the exterior,
wherein the water cooling jacket comprises a water cooling block for moving the cooling water in vertical and horizontal directions to radiate heat emitted from side surfaces of the supercapacitors.

15. The supercapacitor module according to claim 14, wherein the water cooling block comprises:
a first water cooling block for containing portions of the supercapacitors disposed in one row among the plurality of supercapacitors; and
a second water cooling block connected to the first water cooling block and containing the other portions of the supercapacitors disposed in one row.

16. The supercapacitor module according to claim 15, further comprising a water cooling connection part for connecting the first and second water cooling blocks to each other, and supplying cooling water to the first and second water cooling blocks.

17. The supercapacitor module according to claim 14, wherein the containing parts have a groove or hole shape formed in a body of the water cooling block, and the body of the water cooling block includes a water channel through which cooling water flows.
